(19) United States
(12) Patent Application Publication
(10) Pub. No.: US 2010/0326704 A1
(43) Pub. Date: Dec. 30, 2010

(54) SOLDERING PAD LAYOUT FOR FLEXIBLE PRINTED CIRCUIT BOARD

(75) Inventors: CHIN-MEI HUANG, Taichung City (TW); CHIN-WEN LO, Taichung City (TW); TSUI-CHUAN WAN, Taichung County (TW); YUEH-FANG WANG, Taichung City (TW)

Correspondence Address: WPAT, PC;INTELLECTUAL PROPERTY ATTORNEYS, 7225 BEVERLY ST., ANNANDALE, VA, 22003, US

(73) Assignee: WINTEK CORPORATION, TAICHUNG (TW)

(21) Appl. No.: 12/495,759

(22) Filed: Jun. 30, 2009

(51) Int. Cl. H05K 1/02

(52) U.S. Cl. 174/254

(57) ABSTRACT

A soldering pad layout for flexible printed circuit board (PCB) is disclosed, which comprises: a top substrate; a middle substrate; and a bottom substrate, being arranged by stacking one over the other successively in parallel. In an exemplary embodiment, there are at least a top routing layer, being sandwiched between the top substrate and the middle substrate, and at least a bottom routing layer, being sandwiched between the middle substrate and the bottom substrate. With the aforesaid soldering pad layout, not only circuit breakage caused by stress concentration on a bended flexible printed circuit board can be prevented, but also the routing path required on the PCB can be shortened and the amount of space for laying out parts on the PCB can be reduced.

### FIELD OF THE INVENTION

The present invention relates to a soldering pad layout for flexible printed circuit board, and more particularly, to a flexible printed circuit board being configured with via holes at positions corresponding to its every soldering pads for electrically connecting the same to its bottom routing layer.

### BACKGROUND OF THE INVENTION

With rapid advance of technology and the improvement of our living quality, the designs for all kinds of consumer electronic products are becoming more and more diversified. Among all those innovated new designs, the so-called clam-shell or foldable design is most welcomed by consumers and thus becoming the main stream in the market. Moreover, almost all of those foldable electronic products adopt the design of configuring a flexible printed circuitboards (FPC) at their bending areas to be used for transmitting electric signals. As the FPC is flexible, light-weighted and thin, it is especially suitable for those consumer electronic products that are designed to be thinner, lighter and smaller.

For meeting the requirement of thinner, lighter and smaller, the parts mounted on flexible printed circuit boards are usually SMT (surface mount technology) parts, which includes resistors, capacitors, inductances, diodes, transistors, integrated circuits (ICs_, light emitting diodes (LEDs), transient voltage suppressor (TVS), crystals, receivers, microphones, buzzers, and so on.

Please refer to FIG. 1 and FIG. 2, which show a conventional flexible printed circuit board. The conventional flexible printed circuit board is substantially a board 10 having a top substrate 11, a middle substrate 12, and a bottom substrate 13 being arranged by stacking one over the other successively, in which there are at least a top routing layer 14, being sandwiched between the top substrate 11 and the middle substrate 12, and at least a bottom routing layer 15, being sandwiched between the middle substrate 12 and the bottom substrate 13. It is noted that the top substrate 11 and the bottom substrate 13 are acting as protective layer which are respectively configured with adhesive layers 16 to be used for adhering the top substrate 11 and the bottom substrate 13 onto the two opposite surfaces of the middle substrate 12 in respective while sandwiching the top routing layer 14, the middle substrate 12 and the bottom routing layer 15 in between. Moreover, the top substrate 11, the middle substrate 12 and the bottom substrate 13 are all made of non-conductive materials while the top routing layer 14 and the bottom routing layer 15 are made of conductive materials, such as copper foil.

As shown in FIG. 1, there are a plurality of soldering pads, arranged in pairs as the two exemplary soldering pads 17, 17a, which are made of a solder paste and are formed on the top routing layer 14 in a stacking manner while being arranged to expose out of the top substrate 11 and the same time electrically connecting to the top routing layer 14. Each pair of the soldering pads 17, 17a are symmetrically arranged with respect to each other and thus are provided for an electronic part to mount thereon. Taking the soldering pad 17 shown in FIG. 2 for example, it is arranged to piece through the top substrate 11 and the adhesive layer 16 while maintaining electrical conduction with the top routing layer 14. In an actual application, the top routing layer 14 is designed to extend from a side of the soldering pad 17 by a specific length so as to engage with a via hole 18 and thus achieve electrical conduction with the bottom routing layer 15 through a conductive material 181 filled inside the via hole 18, and thereby, the soldering pad 17 is electrically conducted with the bottom routing layer 15.

However, the aforesaid conventional soldering pad layout has many shortcomings, which are listed in the following:
(1) As the pair of soldering pads 17, 17a are adapted for an electronic part to mount thereon and thus in a way that the paired soldering pads 17, 17a are supported by the rigidity of the electronic part, it is inevitable that there will be stress concentration occurred in the neighborhood of the paired soldering pads 17, 17a when the board 10 is bended by an external force during assembly. Because of the stress concentration, the top routing layer 14 may be broken which adversely affect the electrical conduction of the top routing layer 14 and thus the electronic part may not be able to function normally, as shown in FIG. 3.
(2) As the top routing layer 14 is designed to extend from a side of the paired soldering pads 17, 17a, it will required long routing path and larger layout space that not only it is costly, but also it is quite the opposite for achieving an electronic product that is thinner, lighter and smaller.
(3) As there are limited layout space available on any printed circuit board, it is impossible to design a circuit layout which has each and every routing thereof to be orientated parallel and conforming with the bending stress lines produced by the bending of the printed circuit board.

Therefore, it is in need of a soldering pad layout for flexible printed circuit board, which is able to prevent the layout of the flexible printed circuit board from being broken by stresses concentrating around its soldering pads.

### SUMMARY OF THE INVENTION

In view of the disadvantages of prior art, the object of the present invention is to provide a soldering pad layout for flexible printed circuit board, not only capable of effectively prevent the layout of the flexible printed circuit board from being broken by stresses concentrating around its soldering pads, but also capable of shortening the routing path required on the flexible printed circuit board for saving layout space so as to achieve the manufacturing of electronic products with less cost that are thinner, lighter and smaller.

To achieve the above object, the present invention provides soldering pad layout for flexible printed circuit board, which comprises: a top substrate; a middle substrate; and a bottom substrate, being arranged by stacking one over the other successively in parallel; wherein, there are at least a top routing layer, being sandwiched between the top substrate and the middle substrate, and at least a bottom routing layer, being sandwiched between the middle substrate and the bottom substrate. In addition, the soldering pad layout further comprises: at least a soldering pad, each being formed on the top routing layer in a stacking manner while arranging the same to be exposed out of the top substrate and the same time electrically connecting to the top routing layer; and at least a conductive via hole, being formed at a position corresponding to the at least one soldering pad while boring through the top routing layer, the middle substrate and the bottom routing layer successively for enabling the via hole to electrically conduct the top routing layer with the bottom routing layer.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a top view showing a portion of a conventional flexible printed circuit board.

FIG. 2 is an A-A cross sectional view of FIG. 1.

FIG. 3 is an enlarged diagram showing a cross section of a conventional flexible printed circuit board which is bended by an external force.

FIG. 4 is a top view showing a flexible printed circuit board of the invention.

FIG. 5 is a B-B cross sectional view of FIG. 4.

FIG. 6 is an enlarged diagram showing a cross section of a flexible printed circuit board of the invention which is bended by an external force.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

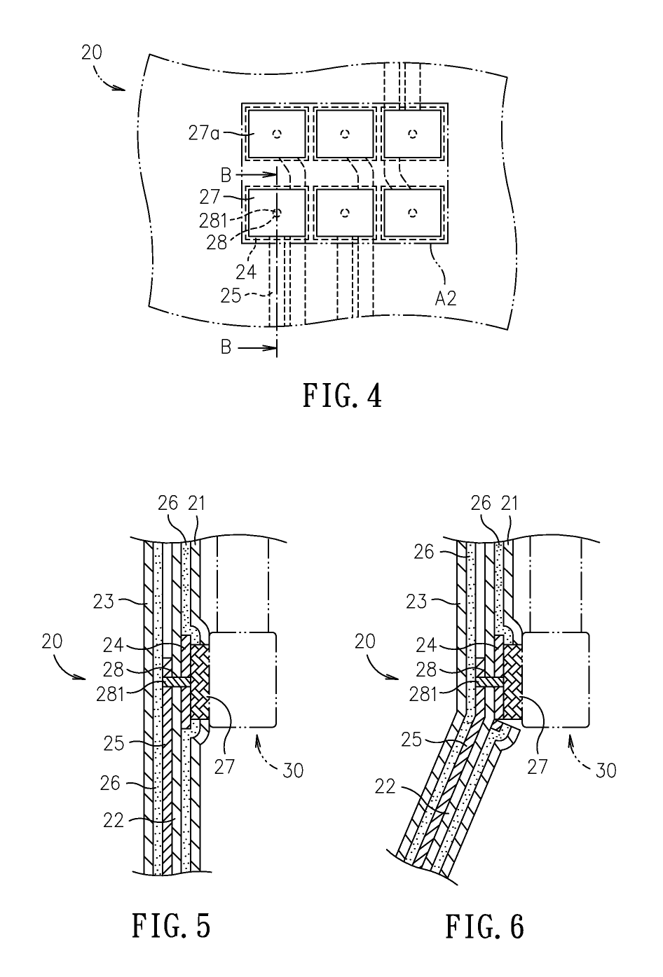

Please refer to FIG. 4 and FIG. 5, which show a soldering pad layout for flexible printed circuit board of the invention. The soldering pad layout for flexible printed circuit board includes a board 20, which comprises a plurality of substrates, including a top substrate 21, a middle substrate 22 and a bottom substrate 23 being arranged by stacking one over the other successively. In addition, there are at least a top routing layer 24 being sandwiched between the top substrate 21 and the middle substrate 22, and at least a bottom routing layer 25, being sandwiched between the middle substrate 22 and the bottom substrate 23. The top substrate 21 and the bottom substrate 23 are formed with a passivation layer respectively. Moreover, there is an adhesive layer 26 being arranged at a position between the top routing layer 24 and the top substrate 21 so as to be used for fixedly securing the stacking of the top substrate 21, the top routing layer 24 and the middle substrate 22. Similarly, there is another adhesive layer 26 being arranged at a position between the bottom routing layer 25 and the bottom substrate 23 so as to be used for fixedly securing the stacking of the bottom substrate 23, the bottom routing layer 25 and the middle substrate 22. It is noted that the top substrate 21, the middle substrate 22 and the bottom substrate 23 are all made of non-conductive materials while the top routing layer 24 and the bottom routing layer 25 are made of conductive materials, such as copper foil.

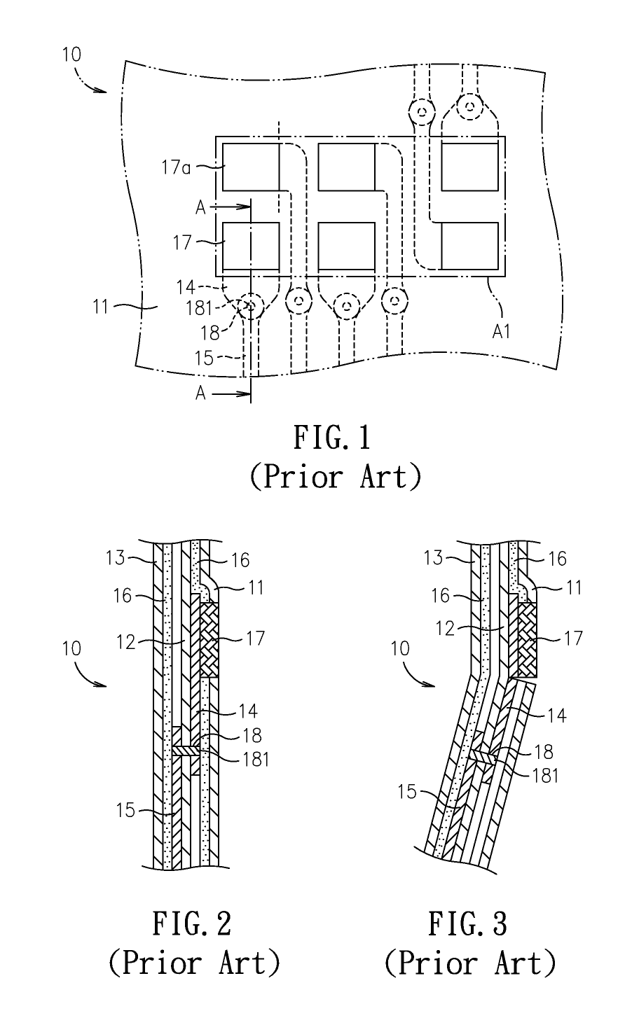

In the embodiment shown in FIG. 1, there are a plurality of soldering pads, arranged in pairs as the two exemplary soldering pads 27, 27a, which are made of a solder paste and are formed on the top routing layer 24 in a stacking manner while being arranged to expose out of the top substrate 21 and the same time electrically connecting to the top routing layer 24. Each pair of the soldering pads 27, 27a are symmetrically arranged with respect to each other and thus are provided for an electronic part to mount thereon by connecting its anode and cathode to the paired soldering pads 27, 27a in respective. Taking the soldering pad 27 shown in FIG. 5 for example, it is in contact with the top routing layer 24 for achieving electrical conduction therewith. It is emphasized that the top routing layer is only provided for the soldering pad 27 to be fixedly soldered on the board 20 as it is formed that there is no restriction regarding to its size and shape. In this embodiment, the top routing layer with respect to the soldering pad 27 is shaped like a rectangle that is slightly larger than that of the soldering pad 27.

The soldering layout of the invention is characterized in that: at the bottom of the top routing layer 24 which is connecting with the soldering pad 27, there is at least via hole 28 being formed at a position corresponding to the soldering pad 27 while boring through the top routing layer 24, the middle substrate 22 and the bottom routing layer 25 successively. For enabling the via hole 28 to be conductive, the via hole 28 can be filled with a conductive material, such as silver adhesive and the like. In addition, by embedding a conductive tube, such as a copper tube, into the via hole 28 can also enable the via hole 28 to be conductive. Thereby, the soldering pad 27 is electrically conducted with the bottom routing layer 25 by the via hole 28 formed at the bottom thereof.

Please refer to FIG. 6, is an enlarged diagram showing a cross section of a flexible printed circuit board of the invention which is bended by an external force. In FIG. 6, it is noted that when the board 20 is bended by an external force, there are still stresses concentrating around the soldering pad 27 that causes the top substrate 21 and the top routing layer 24 around the soldering pad to break accordingly as well. However, although the top substrate 21 and the top routing layer 24 are broken, the soldering pad 27 is still capable of maintaining its electrical conductivity with the bottom routing layer 25 through its via hole 28 so that the electronic part 30 mounted on the soldering pad 27 is still electrically conducted with the bottom routing layer 25. Thereby, the abnormality of circuit breakage while bending a flexible printed circuit board can be prevented.

To sum up, the soldering pad layout for flexible printed circuit board of the invention has the following advantages:
(1) It is able to prevent the circuit layout of a bended flexible printed circuit board from being broken by stresses concentrating around its soldering pads so that the abnormality of electronic parts mounted on the bended flexible printed circuit board can be prevented.
(2) By the forming of a via hole from the bottom of each soldering pad all the way to its bottom routing layer, the routing path of the flexible printed circuit board can be shortened.
(3) The routing of the electronic parts can be protected effectively for preventing the same from peeling off or broken by the bending of an external force.
(4) As it requires less layout space, the manufacturing of thinner, lighter and smaller electronic products with less cost can be achieved. Comparing the six-soldering-pads layouts of FIG. 4 with the one in FIG. 1, it is evident that the layout area A2 of the invention shown in FIG. 4 is far smaller that the conventional layout area A1 shown in FIG. 4.
(5) The product yield can be raised.
(6) The structural difference between the present invention and the prior art is only at the formation of the via hole, which can be achieved without causing significant cost increasing.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A soldering pad layout for flexible printed circuit board, comprising:
a plurality of substrates, including a top substrate; a middle substrate; and a bottom substrate, being arranged by stacking one over the other successively in parallel;
at least a top routing layer, being sandwiched between the top substrate and the middle substrate;
at least a bottom routing layer, being sandwiched between the middle substrate and the bottom substrate;
at least a soldering pad, each being formed on the top routing layer in a stacking manner while arranging the same to be exposed out of the top substrate and the same time electrically connecting to the top routing layer; and
at least a conductive via hole, being formed at a position corresponding to the at least one soldering pad while boring through the top routing layer, the middle substrate and the bottom routing layer successively for enabling the via hole to electrically conduct the top routing layer with the bottom routing layer.

2. The soldering pad layout of claim 1, wherein the at least one soldering pad is provided for an electronic part to connected therewith electrically.

3. The soldering pad layout of claim 1, wherein the at least one soldering pad is two by two paired in a manner that one of two paired soldering pads is connected to an anode of an electronic part while providing another one of the two paired soldering pads to connect to an cathode of the same electronic part.

4. The soldering pad layout of claim 1, further comprising:
an adhesive layer, arranged at a position between the top routing layer and the top substrate so as to be used for fixedly securing the stacking of the top substrate, the top routing layer and the middle substrate.

5. The soldering pad layout of claim 1, further comprising:
an adhesive layer, arranged at a position between the bottom routing layer and the bottom substrate so as to be used for fixedly securing the stacking of the bottom substrate, the bottom routing layer and the middle substrate.

6. The soldering pad layout of claim 4, further comprising:
an adhesive layer, arranged at a position between the bottom routing layer and the bottom substrate so as to be used for fixedly securing the stacking of the bottom substrate, the bottom routing layer and the middle substrate.

7. The soldering pad layout of claim 1, wherein there is a conductive material being filled inside the at least one via hole.

8. The soldering pad layout of claim 7, wherein the conductive material is silver adhesive.

9. The soldering pad layout of claim 1, wherein there is a conductive tube being arranged inside the at least one via hole.

10. The soldering pad layout of claim 9, wherein the conductive tube is a copper tube.
